(19) United States
(12) Patent Application Publication
(10) Pub. No.: US 2024/0429304 A1
(43) Pub. Date: Dec. 26, 2024

(54) ACTIVE REGION TRIMMING AFTER FORMATION OF SOURCE/DRAIN COMPONENTS

(71) Applicant: Taiwan Semiconductor Manufacturing Company, Ltd., Hsin-Chu (TW)

(72) Inventors: Che-Chun Lu, Tainan (TW); Guan-Lun Chen, Hsinchu City (TW); Yi-Hsing Chu, Tainan City (TW); Chia-Yi Tseng, Tainan (TW)

(21) Appl. No.: 18/340,843

(22) Filed: Jun. 24, 2023

(51) Int. Cl. H01L 29/66; H01L 21/306; H01L 29/06; H01L 29/10; H01L 29/423; H01L 29/775

(52) U.S. Cl. CPC H01L 29/66439; H01L 21/30604; H01L 29/0673; H01L 29/1033; H01L 29/42392; H01L 29/66545; H01L 29/775; H10B 10/125

(57) ABSTRACT

A dummy gate structure is formed over a plurality of active regions. The dummy gate structure extends in a first horizontal direction in a planar top view. The active regions each extend in a second horizontal direction in the planar top view. The second horizontal direction is different from the first horizontal direction. A plurality of source/drain components is formed over the active regions. A dielectric structure is formed over the source/drain components. The dummy gate structure is then removed. A removal of the dummy gate structure exposes a first segment of each of the active regions. A thickness of the first segment of each of the active regions is reduced in the first horizontal direction.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as the sizes of the transistor components continue to get smaller, it may be more difficult for an active region (e.g., a fin structure of a FinFET) to maintain a relatively linear top view profile. In some cases, the active region may have a wiggly top view profile, which could lead to various fabrication problems that may adversely impact the performance and/or yield of ICs.

Therefore, although existing semiconductor devices have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1A illustrates a three-dimensional perspective view of a FinFET device.

FIG. 1B illustrates a top view of a FinFET device.

FIG. 1C illustrates a three-dimensional perspective view of a multi-channel gate-all-around (GAA) device.

FIGS. 2A-7A illustrate a series of planar top views of a semiconductor device at various stages of fabrication according to embodiments of the present disclosure.

FIGS. 2B-7B illustrate a series of cross-sectional views of a semiconductor device at various stages of fabrication according to embodiments of the present disclosure.

FIGS. 2C-7C illustrate a series of cross-sectional views of a semiconductor device at various stages of fabrication according to embodiments of the present disclosure.

FIGS. 2D-7D illustrate a series of cross-sectional views of a semiconductor device at various stages of fabrication according to embodiments of the present disclosure.

FIG. 8 illustrates a Static Random Access Memory (SRAM) cell according to an embodiment of the present disclosure.

FIG. 9 illustrates an integrated circuit fabrication system according to an embodiment of the present disclosure.

FIG. 10 illustrates flowchart of a method of fabricating a semiconductor device according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor devices, which may be fabricated using field-effect transistors (FETs) such as three-dimensional fin-line FETs (FinFETs) or multi-channel gate-all-around (GAA) devices. FinFET devices have semiconductor fin structures that protrude vertically out of a substrate. The fin structures are active regions, from which source/drain components and/or channel regions are formed. The gate structures partially wrap around the fin structures. GAA devices have multiple elongated nano-structure channels that may be implemented as nano-tubes, nano-sheets, or nanowires.

In recent years, FinFET devices and GAA devices have gained popularity due to their enhanced performance compared to conventional planar transistors. However, as semiconductor device sizes continue to get scaled down, the formation of active regions of FinFET and/or GAA devices may run into potential problems. In more detail, modern FinFET and/or GAA device fabrication may involve forming active regions (e.g., upwardly protruding semiconductor fin structures). It may be desirable to trim the active regions before source/drain components are formed on the active regions. In that regard, trimming the active regions may refer to reducing a thickness of each of the active regions in a horizontal direction, for example, via one or more etching processes. Trimming the active regions is desirable because it may entail certain performance enhancements. For example, thinner active regions (after being trimmed) can achieve a substantial reduction in an off-state electrical current (I_{off}), while not sacrificing much in terms of an on-state electrical current (Iₒₙ).

However, if the active regions are trimmed before source/drain components are epitaxially grown on them, certain issue may arise. For example, when the source/drain components are epitaxially grown on the trimmed active regions, the small size (e.g., the thinness) of the trimmed active regions may adversely affect the epitaxial growth of the source/drain components. In some instances, due to the small size of the active regions as a base for the source/drain epitaxial growth, the epitaxially grown source/drain components may not be able to achieve a sufficiently large size either. As a result, the smaller-than-optimal source/drain components may lead to sub-optimal performance for the ICs within which the source/drain components are implemented.

Another issue associated with trimming the active regions before the formation of the source/drain components is increased risk of electrical shorting. In more detail, due to the thinness of the trimmed active regions, the resulting source/drain components may exhibit a non-linear (e.g., wiggly) profile in a planar top view. For example, rather than being formed as a long and thin rectangle with a substantially straight or linear wall, the trimmed active region may exhibit various twists and turns, or otherwise have a more-than-desired degree of curvature in the planar top view. Such a non-linear top view profile may result in a tightness of space when gate spacers are formed, which could cause the gate spacers to be formed substantially thinner than expected. One of the functionalities provided by the gate spacers is to prevent electrical bridging between adjacent gate electrodes. In other words, the gate electrodes of adjacently located gate structures are prevented from being in physical contact with one another at least in part due to the gate spacers located between them. However, if the gate spacers' thickness is reduced-which may be the case when the active regions exhibit a non-linear top view profile-then the gate spacers may be more prone to break before the gate electrodes are formed. The breakage of the gate spacers may lead to an open path between adjacent gate structures, and the subsequent gate electrode deposition processes may deposit the gate electrode material (e.g., one or more metal-containing material) in such an open path too. Consequently, the adjacent gate electrodes may come into physical contact with one another, thereby resulting in undesirable electrical shorting between the adjacent gate structures that could degrade device performance or lower device yield.

To address the various issues discussed above, the present disclosure performs a trimming process on a first portion of the active regions after the source/drain components have been grown on a second portion of the active regions. In some embodiments, the active region trimming process is not performed until a dielectric isolation structure (e.g., an interlayer dielectric, or ILD) has been formed to cover up the second portion of the active regions. The first portion of the active regions will become exposed in a dummy gate electrode removal process (e.g., as a part of a gate replacement process). The fin trimming process is performed to this exposed first portion of the active regions before the formation of a metal-containing gate (e.g., a high-k metal gate, or HKMG) structure thereon.

It can be seen that according to the process flow of the present disclosure, when the source/drain components are epitaxially grown on the active regions, the active regions have not been trimmed yet. As such, the relatively thick width of the active regions (as a base for the epitaxial growth of the source/drain components thereon) allows the source/drain components to achieve a bigger size, which is beneficial for device performance. In addition, the active region trimming process is performed only to a portion of the active region that is exposed, which is substantially smaller in length than the overall active region. As such, even though the trimmed active region is still thin, it is less prone to exhibit a wiggly top view profile, due to its relatively short length. In other words, the trimmed active regions formed according to the present disclosure can still achieve a substantially straight or linear profile in the top view. The substantially linear profile of the trimmed active regions may improve device performance as well. Furthermore, since the gate spacers have already been formed before the trimming of the active regions, the gate spacers can still achieve their intended thickness, which in turn allows them to better serve the purposes of preventing electrical shorting between adjacent gate electrodes. Therefore, the present disclosure can also achieve better device performance and increased yield due to the reduction in electrical shorting risks.

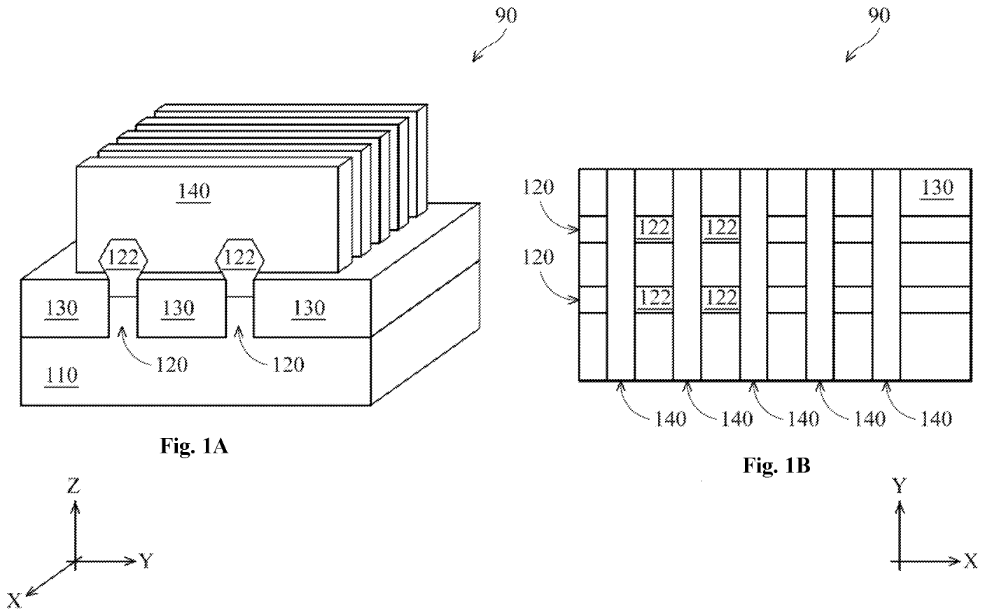

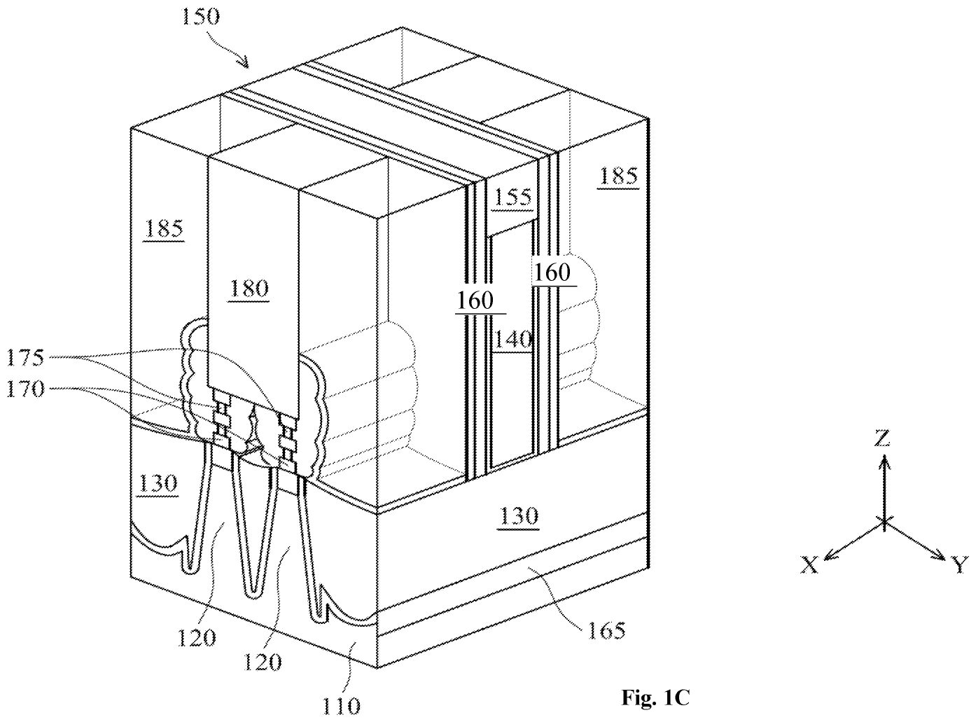

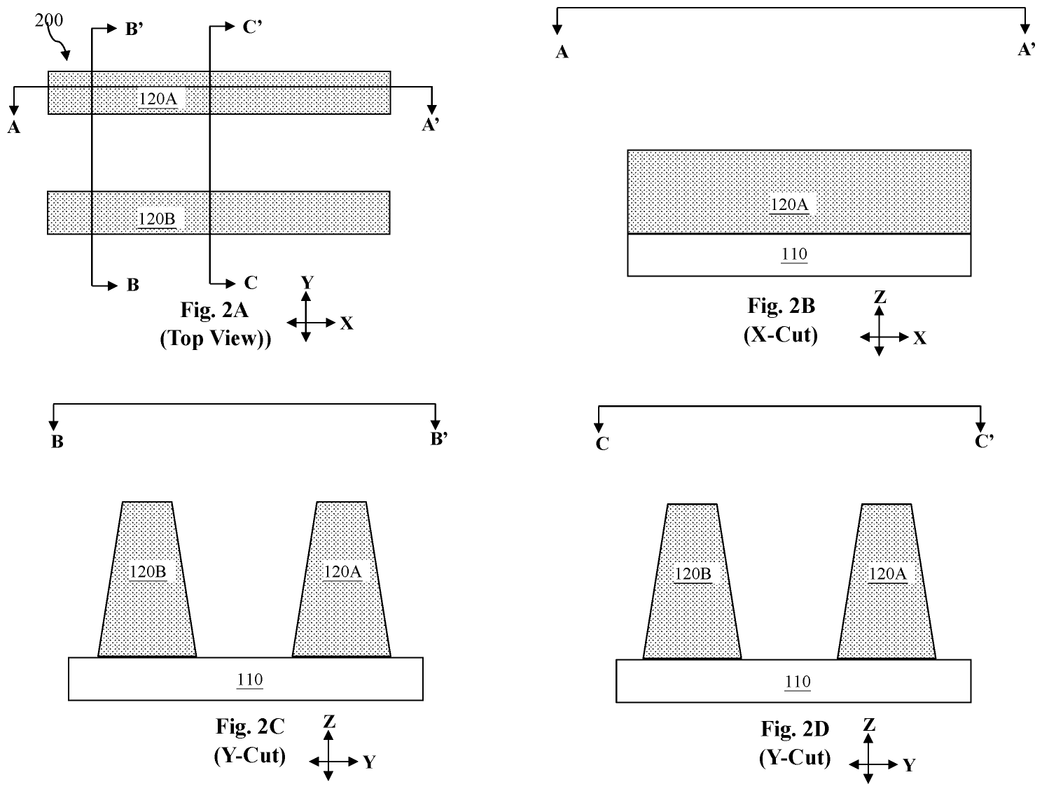

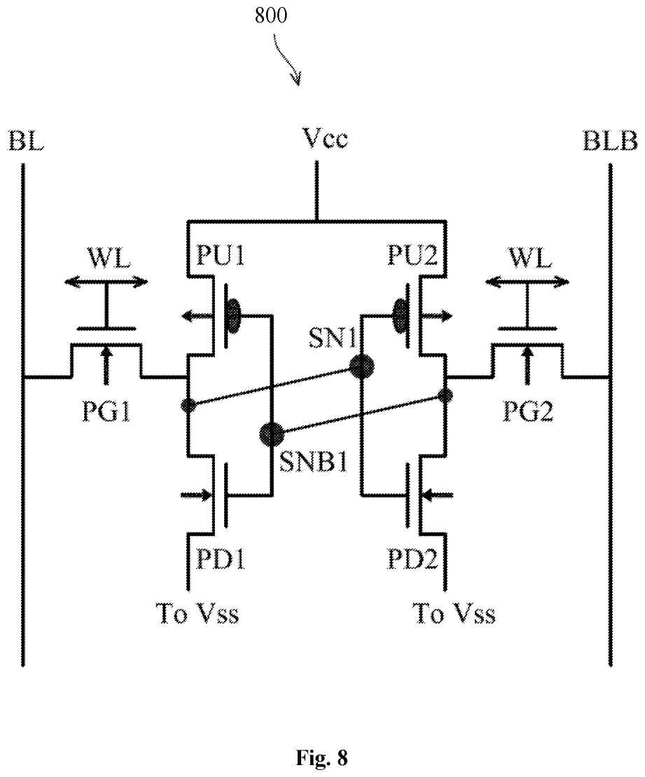

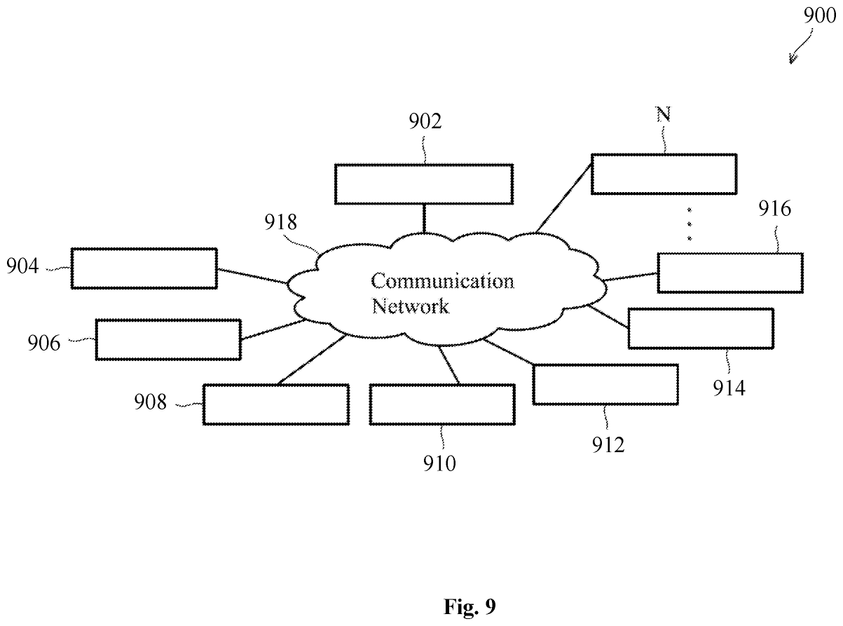

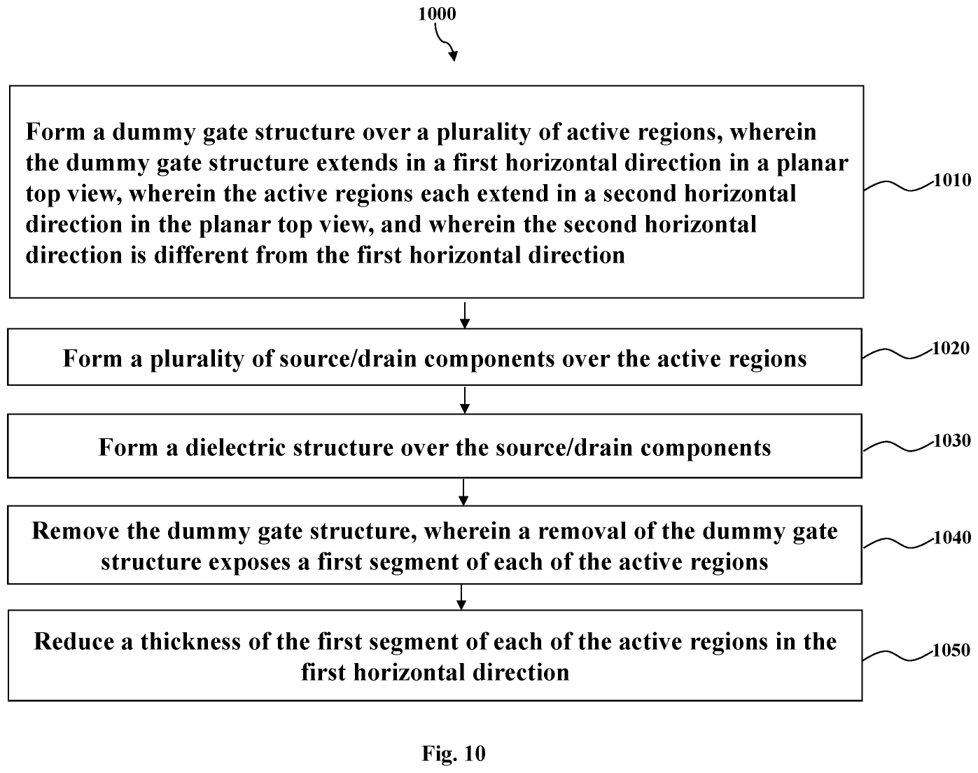

The various aspects of the present disclosure are now discussed below with reference to FIGS. 1A-1C, 2A-7A, 2B-7B, 2C-7C, 2D-7D, and 8-10. In more detail, FIGS. 1A-B illustrate an example FinFET device, and FIG. 1C illustrates an example GAA device. FIGS. 2A-7A illustrate planar top views of an IC device at various stages of fabrication according to embodiments of the present disclosure. FIGS. 2B-7B, 2C-7C, and 2D-7D illustrate different cross-sectional side views of the IC device at various stages of fabrication according to embodiments of the present disclosure. FIG. 8 illustrates a memory circuit as an example IC application implemented using IC devices fabricated according to the various aspects of the present disclosure. FIG. 9 illustrates an example semiconductor fabrication system. FIG. 10 illustrates a flowchart of a method of fabricating a semiconductor device.

Referring now to FIGS. 1A and 1B, a three-dimensional perspective view and a top view of a portion of an Integrated Circuit (IC) device 90 are illustrated, respectively. The IC device 90 is implemented using FinFETs. As shown in FIG. 1A, the IC device 90 includes a substrate 110, for example, a silicon substrate. Three-dimensional active regions 120 are formed on the substrate 110. The active regions 120 may include elongated fin-like structures that protrude upwardly out of the substrate 110. As such, the active regions 120 may be interchangeably referred to as fin structures 120 or fins 120 hereinafter. The IC device 90 also includes source/drain components 122 formed over the fin structures 120. The source/drain components 122 may include epi-layers that are epitaxially grown on the fin structures 120.

The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fin structures 120 on three sides in a channel region of each fin 120. In other words, the gate structures 140 each wrap around a plurality of fin structures 120. The gate structures 140 may be dummy gate structures (e.g., containing an oxide gate dielectric and a polysilicon gate electrode), or they may be HKMG structures that contain a high-k gate dielectric and a metal gate electrode, where the HKMG structures are formed by replacing the dummy gate structures. Though not depicted herein, the gate structure 140 may include additional material layers, such as an interfacial layer over the fin structures 120, a capping layer, other suitable layers, or combinations thereof.

Referring to FIGS. 1A-1B, multiple fin structures 120 are each oriented lengthwise along the X-direction, and multiple gate structure 140 are each oriented lengthwise along the Y-direction, i.e., generally perpendicular to the fin structures 120. In many embodiments, the IC device 90 includes additional features such as gate spacers disposed along sidewalls of the gate structures 140, hard mask layer(s) disposed over the gate structures 140, and numerous other features.

FIG. 1C illustrates a three-dimensional perspective view of an example GAA device 150. For reasons of consistency and clarity, similar components in FIG. 1C and FIGS. 1A-1B will be labeled the same. For example, active regions such as fin structures 120 rise vertically upwards out of the substrate 110 in the Z-direction. The isolation structures 130 provide electrical separation between the fin structures 120. The gate structure 140 is located over the fin structures 120 and over the isolation structures 130. A mask 155 is located over the gate structure 140, and gate spacers 160 are located on sidewalls of the gate structure 140. A capping layer 165 is formed over the fin structures 120 to protect the fin structures 120 from oxidation during the forming of the isolation structures 130.

A plurality of nano-structures 170 are disposed over each of the fin structures 120. The nano-structures 170 may include nano-sheets, nano-tubes, or nano-wires, or some other type of nano-structure that extends horizontally in the X-direction. Portions of the nano-structures 170 under the gate structure 140 may serve as the channels of the GAA device 150. Dielectric inner spacers 175 may be disposed between the nano-structures 170. In addition, although not illustrated for reasons of simplicity, each stack of the nano-structures 170 may be wrapped around circumferentially by a gate dielectric as well as a gate electrode. In the illustrated embodiment, the portions of the nano-structures 170 outside the gate structure 140 may serve as the source/drain features of the GAA device 150. However, in some embodiments, continuous source/drain features may be epitaxially grown over portions of the fin structures 120 outside of the gate structure 140. Regardless, conductive source/drain contacts 180 may be formed over the source/drain features to provide electrical connectivity thereto. An interlayer dielectric (ILD) 185 is formed over the isolation structures 130 and around the gate structure 140 and the source/drain contacts 180.

FIGS. 2A-7A are diagrammatic fragmentary planar top views of a portion of an IC device 200 at various stages of fabrication, and FIGS. 2B-7B, 2C-7C, and 2D-7D are diagrammatic fragmentary cross-sectional side views of a portion of the IC device 200 at various stages of fabrication according to embodiments of the present disclosure. Specifically, FIGS. 2A-7A are planar top views of a horizontal plane defined by an X-direction and a Y-direction, FIGS. 2B-7B are cross-sectional side views of a vertical plane defined by the X-direction and a Z-direction, FIGS. 2C-7C are cross-sectional side views of another vertical plane defined by the Y-direction and the Z-direction, and FIGS. 2D-7D are cross-sectional side views of yet another vertical plane defined by the Y-direction and the Z-direction. The cross-section of FIGS. 2B-7B is taken along a cutline A-A′ shown in the planar top view of FIGS. 2A-7A, the cross-section of FIGS. 2C-7C is taken along a cutline B-B′ shown in the planar top view of FIGS. 2A-7A, and the cross-section of FIGS. 2D-7D is taken along a cutline C-C′ shown in the planar top view of FIGS. 2A-7A, respectively.

Referring to FIGS. 2A-2D, the IC device 200 includes the substrate 110 discussed above with reference to FIGS. 1A-1C. The substrate 110 may include an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. In some embodiments, the substrate 110 may be a single-layer material having a uniform composition. In alternative embodiments, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Still referring to FIGS. 2A-2D, active regions 120 are formed on the substrate 110. The active regions 120 may be three-dimensional structures. For example, the active regions 120 may include elongated fin-like structures that protrude vertically upwards (e.g., in the Z-direction) out of the substrate 110. It is understood that, although the active regions are illustrated herein as fin structures 120 for reasons of simplicity, the concepts of the present disclosure apply to the GAA device with nano-structure active regions as well.

The active regions 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the active regions 120 on the substrate 110. The etching process may include dry etching, wet etching, reactive ion etching (RIE), and/or other suitable processes. In some embodiments, the active region 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers may be formed alongside the patterned layer using a self-aligned process. The layer is then removed, and the remaining spacers, or mandrels, may then be used to pattern the active regions 120.

For reasons of simplicity, two example active regions 120A and 120B are illustrated herein, though it is understood that any number of active regions may be implemented in various embodiments. As shown in the top view of FIG. 2A, the active regions 120A and 120B each extend horizontally in the X-direction, and the active regions 120A and 120B are spaced apart from one another horizontally in the Y-direction. In other words, the active regions 120A and 120B may each be shaped similar to a rectangle in the top view, where the rectangles are elongated in the X-direction and are substantially parallel to one another. Note that at this stage of fabrication, the cross-sectional side view corresponding to FIG. 2C may be substantially identical to the cross-sectional side view corresponding to FIG. 2D. It is understood that due to fabrication process constraints, the edges of the active regions 120A and 120B in actually-fabricated IC devices may not be perfectly straight but may have various small protrusions, recesses, and/or curvatures.

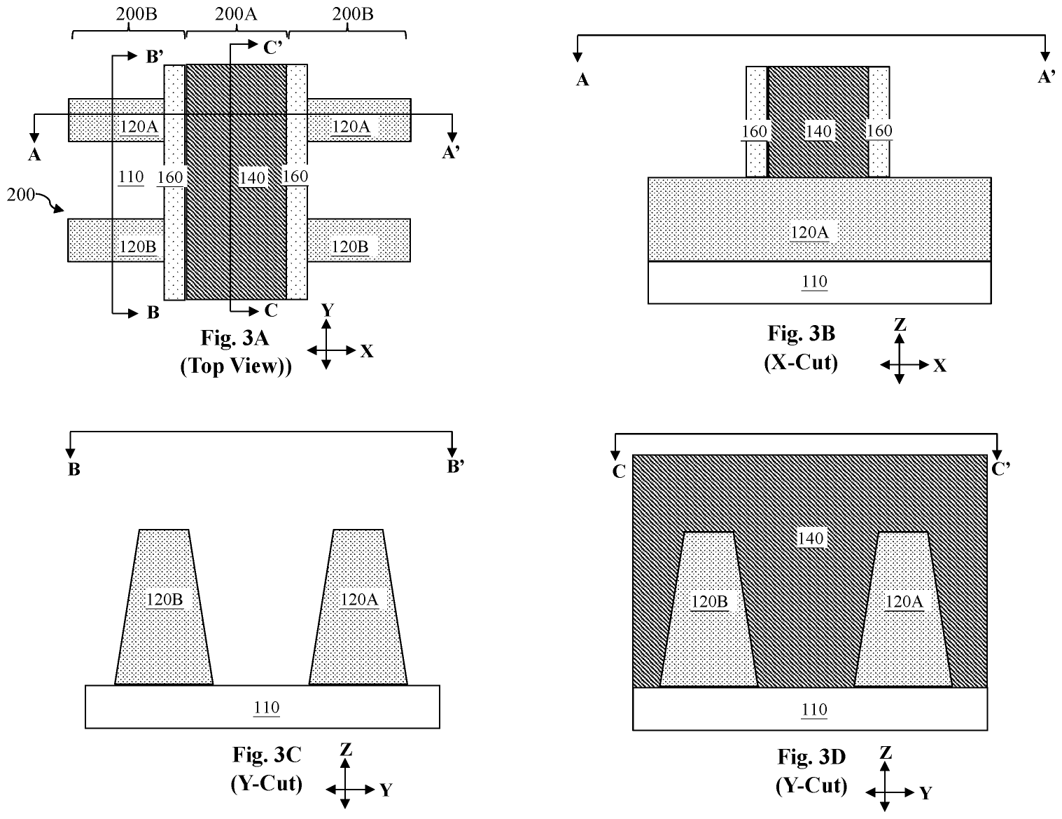

Referring now to FIGS. 3A-3D, dummy gate structures may be formed over the active regions 120A-120B and over the substrate 110. For reasons of simplicity, one example dummy gate structure 140 is illustrated herein, though it is understood that any number of dummy gate structures may be implemented in various embodiments. The dummy gate structure 140 may include a dummy gate dielectric and a dummy gate electrode that is formed over the dummy gate electric. In some embodiments, the dummy gate dielectric may include a silicon oxide material, and the dummy gate electrode may include a polysilicon material.

As shown in the top view of FIG. 3A, the dummy gate structure 140 is formed in a region 200A of the IC device 200, but not in a region 200B of the IC device 200. The dummy gate structure 140 extends horizontally in the Y-direction and spans over (or overlaps with) both of the active regions 120A and 120B in the top view of FIG. 3A. The dummy gate structure 140 is also formed to at least partially wrap around each of the active regions 120A and 120B, as shown in the cross-sectional side view of FIG. 3D. For example, the dummy gate structure 140 wraps around the top and side surfaces of each of the active regions 120A and 120B. Note that the gate structure 140 is not shown in FIG. 3C. This is because the cross-sectional cut corresponding to FIG. 3C is taken along the cutline B-B′, which is located in the region 200B but not in the region 200A where the dummy gate structure 140 is formed.

Gate spacer structures may also be formed on sidewalls of the dummy gate structure 140. For example, the gate spacer structure may include gate spacers 160, as shown in FIGS. 3A and 3B. The gate spacers 160 may be formed by various dielectric material deposition processes and subsequent etching processes. For example, the gate spacers 160 may include one or more dielectric materials, such as silicon oxide (SiO₂), silicon nitride (SiN), silicon oxynitride (SiON), silicon oxycarbide (SiOC), silicon carbon nitride (SiCN), silicon oxycarbon nitride (SiOCN), etc. In some embodiments, each of the gate spacers 160 may actually include a plurality of different gate spacer layers, where at least some of the gate spacer layers have differential material compositions than a rest of the gate spacer layers. For example, in some embodiments, one of the gate spacer layers may have a silicon nitride material composition, while another one of the gate spacer layers may have a silicon oxide material composition. For reasons of simplicity, however, the plurality of different gate spacer layers may be collectively illustrated as a single spacer structure 160 in FIGS. 3A and 3B herein.

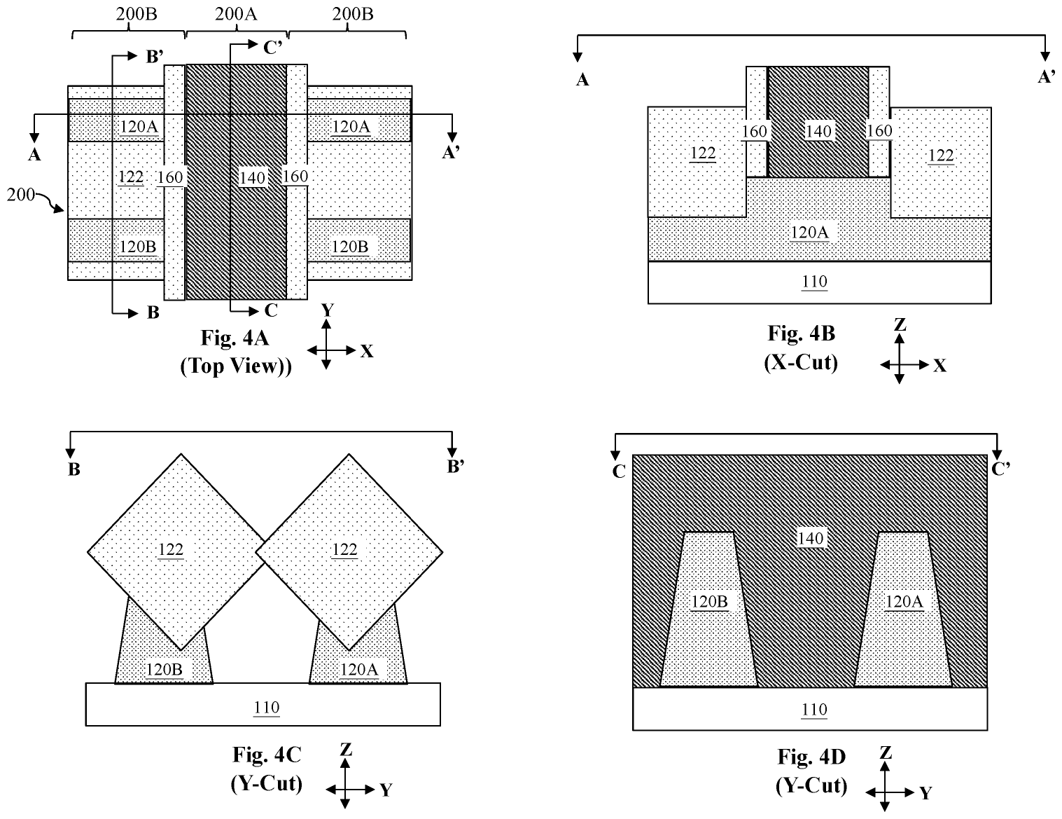

Referring now to FIGS. 4A-4D, source/drain components 122 are formed over the fin structures 120. As used herein, a source/drain component, or a “S/D component” or “S/D region,” may refer to a source or a drain of a device such as a transistor. It may also refer to a component or a region that provides a source and/or drain for multiple devices. Here, the source/drain components 122 may include epi-layers that are epitaxially grown on the active regions 120. In some embodiments, portions of the active regions 120A and 120B may be recessed (e.g., via one or more etching processes) downwardly in the Z-direction, and thereafter the source/drain components 122 are epitaxially grown over the recessed surfaces of the active regions 120A and 120B.

Note that since the source/drain components 122 are formed above (in the vertical Z-direction) the active region 120A and 120B at this stage of fabrication, the active regions 120A and 120B may not be directly visible in a planar top view. Nevertheless, the active regions 120A and 120B are still shown in FIG. 4A to provide an illustration of their locations in order to facilitate the understanding of the various aspects of the present disclosure. Also note that due to the presence of the dummy gate structure 140, the source/drain components 122 are formed in the region 200B but may not be formed in the region 200A of the IC device 200.

One of the benefits of the present disclosure is that the source/drain components 122 formed herein can achieve relatively large sizes. For example, as shown in FIGS. 4A and 4C, the source/drain components 122 formed on adjacent active regions 120A and 120B are large enough, such that they merge into each other laterally in the Y-direction. One of the reasons that the source/drain components 122 can achieve relatively large sizes is the sufficiently wide width of the active regions 120A and 120B, on which the source/drain components 122 are formed. As discussed above, had source/drain components been formed on active regions that have been trimmed already, the reduced thickness of the active regions may lead to poor epitaxial growth of the source/drain components. The poorly grown source/drain components may not achieve a sufficiently large size, which may result in poor electrical performance. In comparison, one of the aspects of the present disclosure pertains to the formation of the source/drain components 122 before the trimming of the active regions 120A and 120B. Since the active regions 120A and 120B have not been trimmed yet, they are still relatively wide (e.g., in the Y-direction) at this stage of fabrication. As a result, the source/drain components 122 can be formed to be relatively large (e.g., wide in the Y-direction), which may result in enhanced electrical performance for the IC device 200.

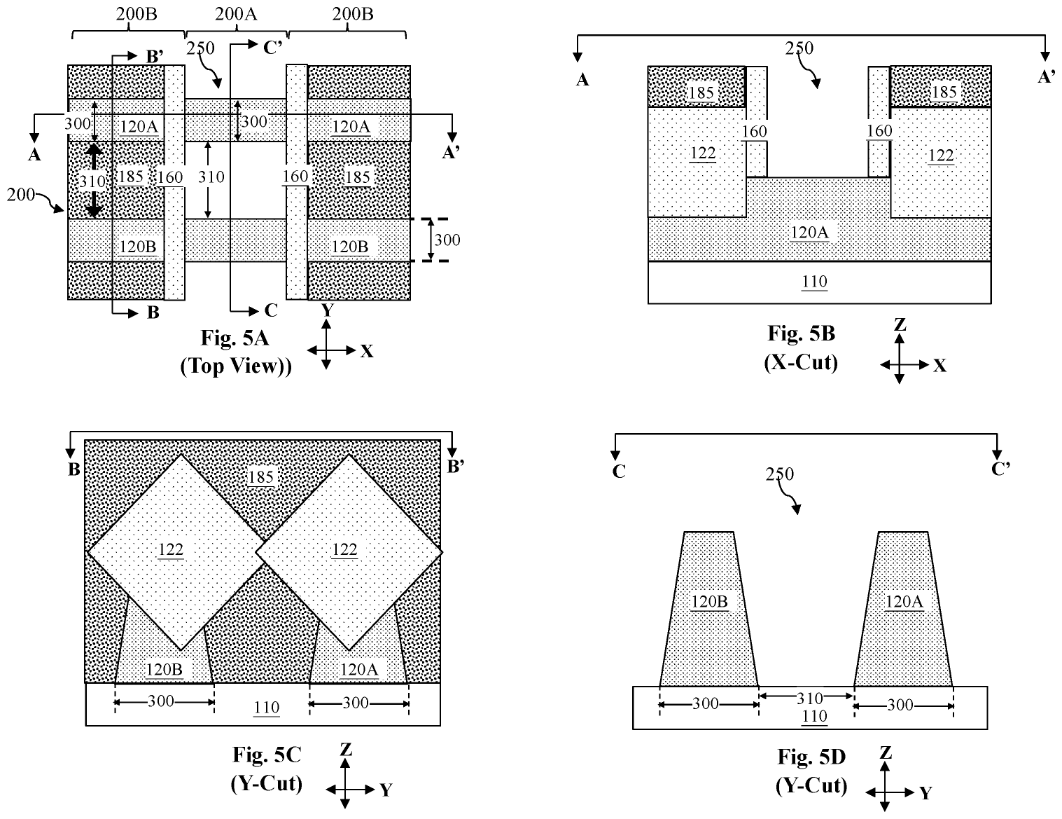

Referring now to FIGS. 5A-5D, a dielectric structure 185 is formed in the region 200B of the IC device 200. In some embodiments, the dielectric structure 185 may be the interlayer dielectric (ILD) structure discussed above and may include silicon dioxide or a low-k dielectric (e.g., having a dielectric constant less than that of silicon dioxide) material. The dielectric structure 185 is formed over the active regions 120A and 120B, as well as over the source/drain components 122. The formation of the dielectric structure 185 may include one more deposition processes, followed by one or more polishing processes such as CMP. In order to facilitate the ensuing discussions, the active regions 120A and 120B are still illustrated in the planar top view of FIG. 5A (even though the active regions 120A/120B are actually covered up by the dielectric structure 185), but the source/drain components 122 are omitted from FIG. 5A.

Still referring to FIGS. 5A-5D, the dummy gate structure 140 is removed after the formation of the dielectric structure 185. In some embodiments, the dummy gate structure 140 is removed via one or more etching processes. For example, the etching processes may include dry etching or wet etching processes that have sufficient etching selectivity between the materials of the dummy gate structure 140 (e.g., the polysilicon dummy gate electrode and/or the silicon oxide dummy gate dielectric) and other components of the IC device 200 (e.g., the gate spacers 160 and the dielectric structure 185), such that the materials of the dummy gate structure 140 can be etched away without substantially affecting the remaining components of the IC device 200. For example, the gate spacers 160 and the dielectric structure 185 may still remain after the removal of the dummy gate structure 140.

Note that the removal of the dummy gate structure 140 forms an opening 250 (see FIGS. 5A, 5B, and 5D), where the opening 250 exposes a first segment of each of the active regions 120A and 120B in the region 200A of the IC device 200. The opening 250 is defined at least in part by an adjacent pair of the active regions (e.g., the active regions 120A and 120B), as well as by the gate spacers 160.

At this stage of fabrication, the active regions 120A and 120B each have a width 300 (e.g., horizontal dimension) that is measured in the Y-direction. The value of the width 300 is substantially the same for the segments of the active regions 120A and 120B located in the region 200A and for the segments of the active regions 120A and 120B located in the region 200B. In other words, although fabrication constraints may lead to small width variations throughout the length of the active regions 120A and 120B, there is no significant difference between the portions of the active regions 120A/120B exposed by the opening 250 versus the portions of the active regions 120A/120B covered by the dielectric structure 185 at this time. In addition, the adjacent active regions 120A and 120B are spaced apart horizontally in the Y-direction by a distance 310. Similar to the width 300, the value of the distance 310 remains substantially the same in the region 200A and in the region 200B of the IC device 200 at the stage of fabrication shown in FIGS. 5A-5D.

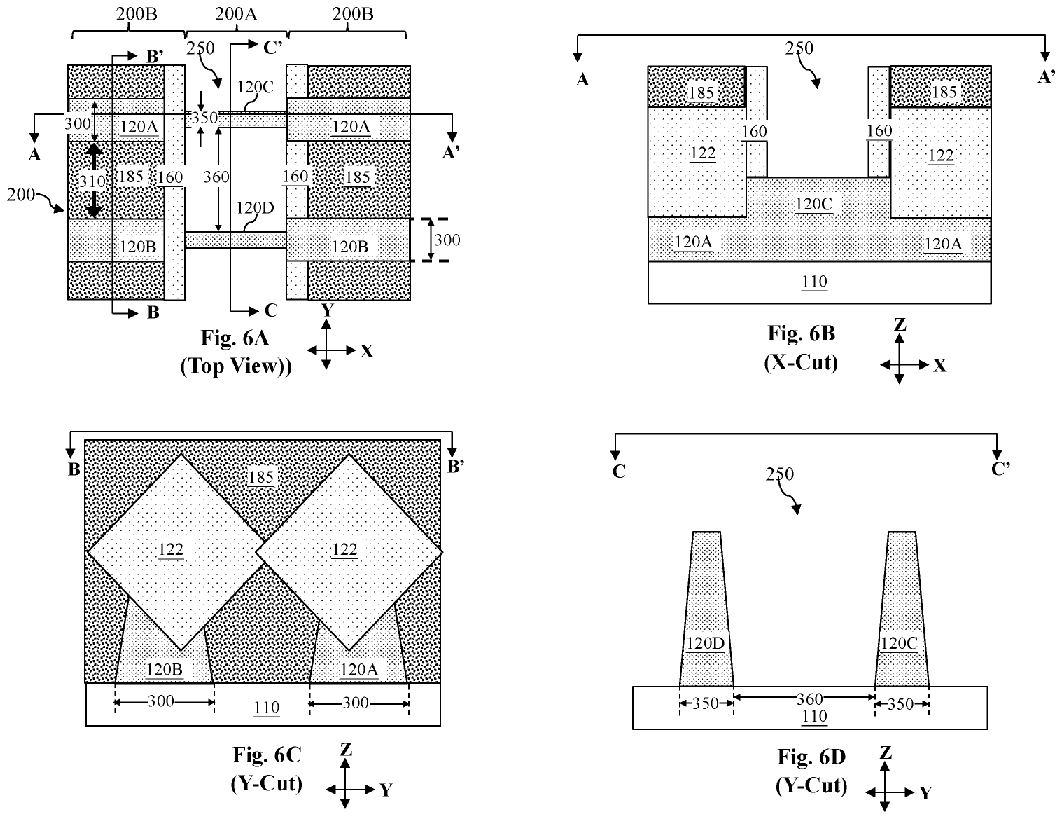

Referring now to FIGS. 6A-6D, an active region trimming process is performed to the IC device 200 to reduce the width of the segments of the active regions 120A and 120B exposed by the opening 250. In some embodiments, the active region trimming process includes one or more etching processes having an etching selectivity between the material of the active regions 120A/120B and the materials of the other components (e.g., the spacers 160 and/or the dielectric structure 185) of the IC device 200. During the active region trimming process, the dielectric structure 185 serves as a protective etching mask for the segments of the active regions 120A and 120B located therebelow, such that these segments are substantially unaffected by the active region trimming process. Meanwhile, the portions of the active regions 120A and 120B exposed by the opening 250 are partially etched away, such that the remaining segments 120C and 120D have substantially reduced dimensions in the Y-direction.

For example, as shown in the top view of FIG. 6A and the cross-sectional side view of FIG. 6D, the remaining segments 120C and 120D of the active regions after the trimming process each have a width 350 that is measured in the Y-direction. Compared to the width 300 of the segments 120A/120B of the active regions covered under the dielectric structure 185, the width 350 is substantially smaller in value. In some embodiments, the width 300 is at least 2 times greater than the width 350 in value. For example, a ratio between the width 300 and the width 350 may be in a range between about 4:1 and about 6:1. Furthermore, due to the reduction in width of the segments 120C and 120D, a now-greater distance 360 separates the segments 120C and 120D of the active regions than before the active region trimming process was performed. In other words, whereas the segments 120A and 120B of the active regions are still separated by the distance 310, the segments 120C and 120D of the active regions are now separated by a substantially greater distance 360. In some embodiments, the distance 360 is at least 1.3 times greater than the distance 310 in value. For example, a ratio between the distance 360 and the distance 310 may be in a range between about 1.3:1 and about 2:1.

It is understood that the above ranges are not randomly chosen but specifically configured to optimize the performance of the IC device 200. For example, if the width 350 is too low or the distance 360 is too high, that may mean that the active region trimming process has been performed excessively. When this occurs, the segments 120C and 120D of the active regions may still be vulnerable for breaking or exhibiting a non-linear (e.g., wiggly) top view profile, which could result in device performance degradations or even device failures. On the other hand, if the width 350 is too high or the distance 360 is too low, that may mean that the active region trimming process has not been performed sufficiently. When this occurs, these segments 120C and 120D of the active regions may not fully achieve the performance improvements associated with trimming the active regions. For example, the transistors associated with the segments 120C and 120D of the active regions may not be able to achieve a sufficient reduction in the off-state electrical current (I_{off}). The above numerical ranges for the width 350 and the distance 360 (and their related ratios) are carefully configured in a manner such that the resulting segments 120C and 120D of the active regions are unlikely to break or exhibit nonlinear top view profiles, while at the same time achieve the benefits associated with active region trimming, for example, a sufficient reduction in the off state electrical current.

It is also understood that the fact that the width 350 of the segment 120C and 120D is smaller than the width 300 of the segments 120A and 120B of the active regions is an inherent result of the unique process flow of the present disclosure being performed, and it may be used as evidence to detect infringement of the process flow of the present disclosure. In more detail, the size discrepancy between the segments 120C/120D and 120A/120B of the active regions is attributable to the fact that the active region trimming process is performed after (instead of before) the formation of the source/drain components 122. Due to this unique process flow, the segments 120A and 120B of the active regions have already been covered up by the dielectric structure 185 by the time the active region trimming process is performed. Therefore, the segments 120A and 120B will retain their original (and larger) width 300.

In contrast, the segments 120C and 120D are trimmed after the formation of the source/drain components 122 and after the dummy gate structure 140 has been removed. The removal of the dummy gate structure 140 leaves the opening 250 that exposes the segments 120C and 120D of the active regions, which allows them to be trimmed to achieve the reduced width 350 (compared to the original width 300). Similarly, the fact that the distance 360 (separating the segments 120C and 120D) is greater than the distance 310 (separating the segments 120A and 120B) is also an inherent result of the unique process flow of the present disclosure being performed. Had an IC device not been fabricated based on the unique process flow of the present disclosure, then the distance separating the segments of the active regions may have been substantially the same in both the regions 200A and 200B of the IC device 200.

Note that the segments 120A and 120C are portions of a continuous active region, although this aspect may not be readily apparent based on the top view of FIG. 6A, as the spacers 160 are located at a portion of the segment 120A of the active region immediately adjacent to the segment 120C. In other words, the segments 120A and 120C are in direct physical contact with one another. For example, and end portion of the segment 120A that is located directly below (vertically in the Z-direction) the spacers 160 may be in physical contact with the segment 120C. In this manner, the segments 120A and 120B collectively make up a continuous active region with varying sizes in the region 200B and 200A of the IC device 200. The segment 120A with the larger width 300 is located in the region 200B of the IC device 200, while segment 120C with the smaller width 350 is located in the region 200A of the IC device 200, where the regions 200A and 200B share an interface that substantially coincides with a side wall of the gate spacer 160 that extends horizontally in the Y-direction in the top view. Likewise, the segments 120B and 120D are also portions of a continuous active region that spans across the regions 200B and 200A of the IC device 200 in the top view.

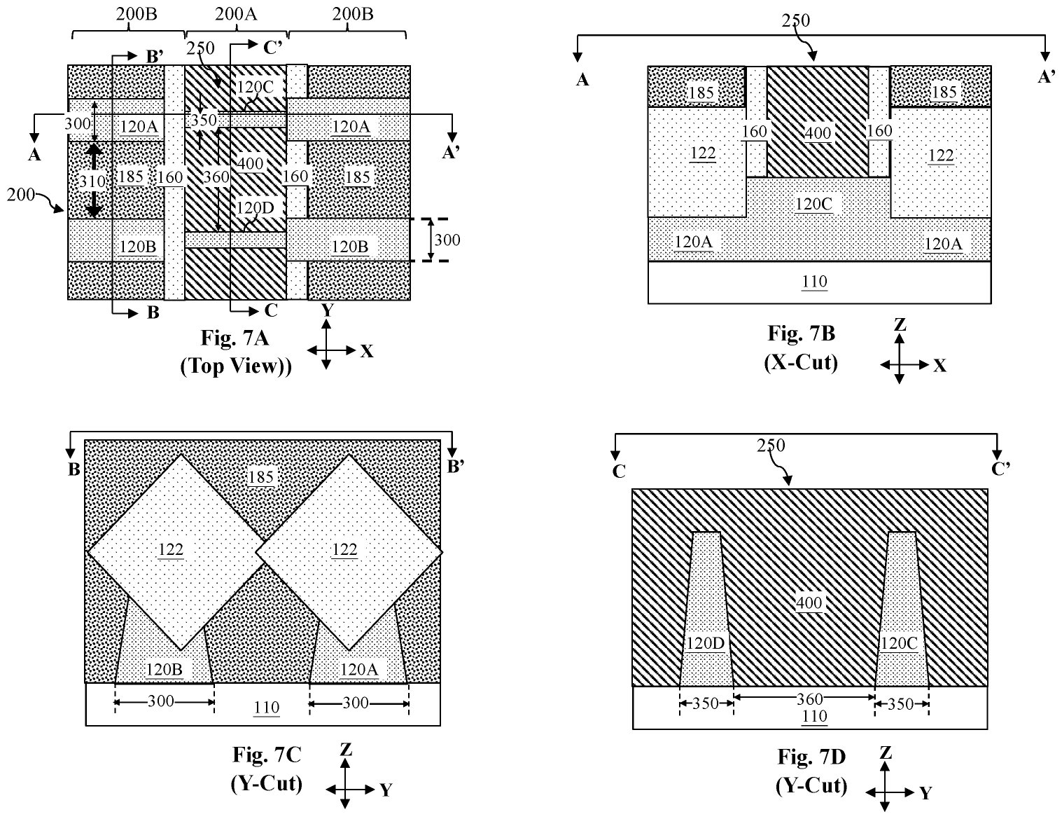

Referring now to FIGS. 7A-7D, a metal-containing gate structure 400 is formed to replace the dummy gate structure 140. For example, one or more deposition processes may be performed to partially fill the opening with a high-k gate dielectric. The high-k gate dielectric contains a high-k dielectric material, which refers to a dielectric material having a dielectric constant that is greater than a dielectric constant of silicon oxide (e.g., which is about 3.9). Example materials of the high-gate k dielectric include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, or combinations thereof.

Thereafter, a metal-containing gate electrode is formed over the high-k gate dielectric. The metal-containing gate electrode may be formed by performing one or more deposition processes to fill the opening 250 with various metal-containing materials, followed by a planarization process (e.g., a CMP process) to planarize an upper surface of the deposited metal-containing materials. As a result, the metal-containing gate electrode may include one or more work function (WF) metal layers and a fill metal layer. The work function metal layers may be configured to tune a work function of the respective transistor. Example materials for the work function metal layers may include titanium nitride (TiN), Titanium aluminide (TiAl), tantalum nitride (TaN), titanium carbide (Tic), tantalum carbide (TaC), tungsten carbide (WC), aluminum titanium nitride (TiAIN), zirconium aluminide (ZrAl), tungsten aluminide (WAl), tantalum aluminide (TaAl), hafnium aluminide (HfAl), or combinations thereof. The fill metal layer may serve as the main conductive portion of the metal-containing gate electrode. In some embodiments, the fill metal layer may include cobalt, tungsten, copper, aluminum, or alloys or combinations thereof. It is understood that the metal-containing gate structure 400 may include additional layers, such as interfacial layers, capping layers, diffusion/barrier layers, or other applicable layers. For reasons of simplicity, these additional layers are not specifically illustrated herein.

Another benefit of the present disclosure is the reduction in electrical shorting risks during the formation of the metal containing gate structure 400. In more detail, had the active regions been trimmed before the formation of the source drain components, the resulting trimmed active regions may exhibit a nonlinear (e.g., wiggly) top view profile. Such a nonlinear profile may lead to a crowding in space between an adjacent pair of active regions. Such a process flow also typically forms the gate spacers after the trimming of the active regions, and the crowding in space between the active regions could lead to poor formation of the gate spacers. For example, the gate spacers may not achieve a target thickness in the X-direction, which may make them more prone to breaking. When gate spacers break, it could form an open path between neighboring gate structures. Thus, when metal-containing materials are deposited to form the metal-containing gate electrodes, the metal-containing gate electrodes from neighboring gate structures may electrically short into one another via the open path (which is also filled with the metal-containing materials during the deposition of the metal-containing materials). Such an electrical shorting between neighboring gate structures may degrade device performance or cause device failures.

The unique fabrication process flow of the present disclosure obviates the electrical shorting problem discussed above, because the gate spacer thickness would not be unduly reduced. This is attributable to the fact that the active regions 120A-120D can achieve greater linearity, since just a small portion (as opposed to an entity) of the active regions needs to be trimmed. The greater linearity of the active regions 120A-120D also means that the crowding issue between adjacent active regions is less likely to occur. And even if there is some degree of crowding between adjacent active regions, it is unlikely to reduce the thickness of the gate spacers 160, since the gate spacers 160 have already been formed (see FIGS. 3A-3B) before portions of the active regions 120C/120D are trimmed (see FIGS. 6A and 6D). For these reasons, the gate spacers 160 can achieve and/or maintain their intended thicknesses in the X-direction, which means that they are unlikely to break. As such, no open path would be formed between the metal-containing gate structure 400 and a neighboring metal-containing gate structure (not specifically illustrated herein). Consequently, the formation of the metal-containing gate structure 400 (e.g., the deposition of the metal-containing materials) will not cause the metal-containing gate structure to electrically short into any neighboring metal-containing gate structure. Such a reduction is electrical shorting risks may translate into an improvement in device performance and/or yield.

It is understood that the IC device 200 discussed above may be implemented in a variety of IC applications, including memory devices such as Static Random-Access Memory (SRAM) devices. In that regard, FIG. 8 illustrates an example circuit schematic for a single-port SRAM cell (e.g., 1-bit SRAM cell) 800. The single-port SRAM cell 800 includes pull-up transistors PU1, PU2; pull-down transistors PD1, PD2; and pass-gate transistors PG1, PG2. As show in the circuit diagram, transistors PU1 and PU2 are p-type transistors, and transistors PG1, PG2, PD1, and PD2 are n-type transistors. Since the SRAM cell 800 includes six transistors in the illustrated embodiment, it may also be referred to as a 6T SRAM cell.

The drains of pull-up transistor PU1 and pull-down transistor PD1 are coupled together, and the drains of pull-up transistor PU2 and pull-down transistor PD2 are coupled together. Transistors PU1 and PD1 are cross-coupled with transistors PU2 and PD2 to form a first data latch. The gates of transistors PU2 and PD2 are coupled together and to the drains of transistors PU1 and PD1 to form a first storage node SN1, and the gates of transistors PU1 and PD1 are coupled together and to the drains of transistors PU2 and PD2 to form a complementary first storage node SNB1. Sources of the pull-up transistors PU1 and PU2 are coupled to power voltage Vcc (also referred to as Vdd), and the sources of the pull-down transistors PD1 and PD2 are coupled to a voltage Vss, which may be an electrical ground in some embodiments.

The first storage node SN1 of the first data latch is coupled to bit line BL through pass-gate transistor PG1, and the complementary first storage node SNB1 is coupled to complementary bit line BLB through pass-gate transistor PG2. The first storage node N1 and the complementary first storage node SNB1 are complementary nodes that are often at opposite logic levels (logic high or logic low). Gates of pass-gate transistors PG1 and PG2 are coupled to a word line WL. SRAM devices such as the SRAM cell 800 may be implemented using the IC device 200 discussed above, which could be implemented as FinFET devices and/or as GAA devices.

FIG. 9 illustrates an integrated circuit fabrication system 900 according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such the processing tools to perform the selective growth process 550 discussed above; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

FIG. 10 is a flowchart illustrating a method 1000 of fabricating a semiconductor device. The method 1000 includes a step 1010 to form a dummy gate structure over a plurality of active regions. The dummy gate structure extends in a first horizontal direction in a planar top view. The active regions each extend in a second horizontal direction in the planar top view. The second horizontal direction is different from the first horizontal direction (e.g., perpendicular to the first horizontal direction).

The method 1000 includes a step 1020 to form a plurality of source/drain components over the active regions.

The method 1000 includes a step 1030 to form a dielectric structure over the source/drain components.

The method 1000 includes a step 1040 to remove the dummy gate structure. A removal of the dummy gate structure exposes a first segment of each of the active regions.

The method 1000 includes a step 1050 to reduce a thickness of the first segment of each of the active regions in the first horizontal direction. In some embodiments, the thickness is reduced by performing one or more etching processes. In some embodiments, the dummy gate structure includes a dummy gate electrode and a gate spacer structure, the removing of the dummy gate structure removes the dummy gate electrode but not the gate spacer structure or the dielectric structure, and the dielectric structure and the gate spacer structure protect portions of the active regions disposed below from being etched during the one or more etching processes.

In some embodiments, each of the active regions includes a second segment that is covered by the dielectric structure, and a thickness of the second segment of each of the active regions is unaffected by the reducing of the thickness of the first segment of each of the active regions in the first horizontal direction.

In some embodiments, for each of the active regions, the first segment is continuous with the second segment after the thickness of the first segment has been reduced.

In some embodiments, the first segment has a first thickness in the first horizontal direction, the second segment has a second thickness in the first horizontal direction, and a ratio between the second thickness and the first thickness is in a range between about 4:1 and about 6:1.

In some embodiments, the forming the plurality of source/drain components is performed via an epitaxial growth process, such that the source/drain components grown on adjacent active regions merge into one another in the first horizontal direction.

It is understood that additional steps may be performed before, during, or after the steps 1010-1050. For example, after the reducing the thickness of the first segment, a metal-containing gate structure is formed over the first segment of each of the active regions. As another example, a plurality of vertically protruding fin structures is formed as the plurality of active regions, wherein the dummy gate structure is formed such that it partially wraps around each of the vertically protruding fin structures. As yet another example, the method 1000 may include the formation of metallization features, such as conductive contacts and/or vias for the gate structures and the source/drain components. As a further example, the method 1000 may include packaging and testing processes. For reasons of simplicity, these additional steps are not discussed in detail herein.

In summary, the present disclosure involves performing a unique process flow to trim the active regions of a transistor. For example, rather than trimming an entirety of an active region before the epitaxial growth of source/drain components, the present disclosure trims just a first segment of an active region after epitaxial growth has been performed to form source/drain components over a second segment of the active region. According to the process flow of the present disclosure, the second segment of the active region is protected by a dielectric structure when the first segment of the active region is trimmed.

The unique fabrication process flow and the resulting IC device structure of the present disclosure offers advantages over conventional devices. It is understood, however, that no particular advantage is required, other embodiments may offer different advantages, and that not all advantages are necessarily disclosed herein. One advantage is the improved performance of IC devices. In more detail, as device sizes are scaled down in newer technology generations, the various IC components are more vulnerable to damage or otherwise not achieving an intended geometric profile. For example, when a trimming process is performed to reduce the lateral dimension of a relatively long active region (e.g., a fin structure), the resulting active region may exhibit a non-linear top view profile (e.g., a wiggly profile), or it may even collapse or otherwise become damaged. In addition, source drain components that are epitaxially grown on active regions that are too thin (due to being trimmed) may not achieve a sufficiently large size either, which could degrade device performance.

Here, the unique fabrication process flow means that a much shorter segment (rather than an entirety) of the active region needs to be trimmed, which allows the trimmed active region to still maintain a relatively linear (e.g., straight) profile. Due at least in part to the smaller length, the trimmed active region herein is also unlikely to collapse or become damaged, thereby improving device performance and/or yield. Furthermore, since the source/drain components are formed before the active region are trimmed, the thicker active region serves as a better base structure upon which the source/drain components can be epitaxially grown. Consequently, the source drain components formed herein can achieve a sufficiently large size, thereby also improving device performance.

Another advantage is the reduction of electrical shorting risks. In that regard, a non-linear profile of the trimmed active region may mean that at certain regions, an adjacent pair of active regions may be located too close to one another. This crowding of active regions in certain regions could cause subsequently-formed gate spacers to not achieve a sufficiently large thickness. When this happens, the gate spacers may not be able to adequately serve as an electrical isolation structure between neighboring gate electrodes. In turn, unintentional electrical shorting between neighboring gate electrodes may occur in a subsequent process. Here, since the trimmed active regions can maintain a relatively linear profile throughout, the unintentional and undesirable crowding between an adjacent pair of active regions is unlikely to occur. Furthermore, since the gate spacers have already been formed before the trimming of the active regions, the gate spacers can still achieve a desired thickness even if there is some degree of crowding between adjacent active regions. As such, the gate spacers of the present disclosure can still adequately serve as a barrier structure between neighboring gate electrodes to prevent an undesirable electrical shorting between these gate electrodes. Other advantages may include ease of fabrication and compatibility with existing fabrication processes.

The advanced lithography process, method, and materials described above can be used in many applications, including fin-type field effect transistors (FinFETs). For example, the fins may be patterned to produce a relatively close spacing between features, for which the above disclosure is well suited. In addition, spacers used in forming fins of FinFETs, also referred to as mandrels, can be processed according to the above disclosure. It is also understood that the various aspects of the present disclosure discussed above may apply to multi-channel devices such as Gate-All-Around (GAA) devices. To the extent that the present disclosure refers to a fin structure or FinFET devices, such discussions may apply equally to the GAA devices.

The advanced lithography process, method, and materials described above can be used in many applications, including fin-type field effect transistors (FinFETs). For example, the fins may be patterned to produce a relatively close spacing between features, for which the above disclosure is well suited. In addition, spacers used in forming fins of FinFETs, also referred to as mandrels, can be processed according to the above disclosure. It is also understood that the various aspects of the present disclosure discussed above may apply to multi-channel devices such as Gate-All-Around (GAA) devices. To the extent that the present disclosure refers to a fin structure or FinFET devices, such discussions may apply equally to the GAA devices.

One aspect of the present disclosure involves a semiconductor device. The semiconductor device includes a first region that includes: a first segment of an active region and a metal-containing gate structure disposed over the first segment of the active region in a vertical direction in a cross-sectional side view. The semiconductor device further includes a second region that includes: a second segment of the active region and a dielectric structure disposed over the second segment of the active region in the vertical direction in the cross-sectional side view. The second segment of the active region is thicker than the first segment of the active region in a planar top view.

Another aspect of the present disclosure involves a method fabricating a semiconductor device. A dummy gate structure is formed over a plurality of active regions. The dummy gate structure extends in a first horizontal direction in a planar top view. The active regions each extend in a second horizontal direction in the planar top view. The second horizontal direction is different from the first horizontal direction. A plurality of source/drain components is formed over the active regions. A dielectric structure is formed over the source/drain components. The dummy gate structure is removed. A removal of the dummy gate structure exposes a first segment of each of the active regions. A thickness of the first segment of each of the active regions is reduced in the first horizontal direction.

Yet another aspect of the present disclosure involves a semiconductor device. The semiconductor device includes an active region that protrudes upwards in a vertical direction in a cross-sectional side view. The semiconductor device includes a gate structure that at least partially wraps around the active region in the cross-sectional side view. The gate structure extends in a first horizontal direction in a top view. The active region extends in a second horizontal direction in the top view. The second horizontal direction is different from the first horizontal direction. A first portion of the active region located outside of the gate structure is thicker in the first direction than a second portion of the active region wrapped under the gate structure.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit line conductor and word line conductor, one can achieve different resistances for the conductors. However, other techniques to vary the resistances of the metal conductors may also be utilized as well.

What is claimed is:

1. A device, comprising:
a first region that includes:
a first segment of an active region; and
a metal-containing gate structure disposed over the first segment of the active region in a vertical direction in a cross-sectional side view; and
a second region that includes:
a second segment of the active region; and
a dielectric structure disposed over the second segment of the active region in the vertical direction in the cross-sectional side view, wherein the second segment of the active region is thicker than the first segment of the active region in a planar top view.

2. The device of claim 1, wherein the active includes a fin structure that protrudes vertically out of a substrate in the cross-sectional side view.

3. The device of claim 1, wherein:
the planar top view is defined by a first horizontal direction and a second horizontal direction perpendicular to the first horizontal direction;
the first region and the second region form an interface in the top view; and
the interface extends in the first horizontal direction in the top view.

4. The device of claim 3, wherein:
the first segment has a first horizontal dimension in the first horizontal direction;
the second segment has a second horizontal dimension in the first horizontal direction; and
a ratio between the second horizontal dimension and the first horizontal dimension is in a range between about 4:1 and about 6:1.

5. The device of claim 1, wherein the first segment of the active region is continuous with the second segment of the active region.

6. The device of claim 1, wherein:
the active region is a first active region;
the device further includes a second active region;
the metal-containing gate structure is disposed over a third segment of the second active region;
the dielectric structure is disposed over a fourth segment of the second active region;
the third segment of the second active region is separated from the first segment of the first active region by a first distance in the planar top view;
the fourth segment of the second active region is separated from the second segment of the first active region by a second distance in the planar top view; and
the first distance is greater than the second distance.

7. The device of claim 6, wherein a ratio between the first distance and the second distance is in a range between about 1.3:1 and about 2:1.

8. A method, comprising:
forming a dummy gate structure over a plurality of active regions, wherein the dummy gate structure extends in a first horizontal direction in a planar top view, wherein the active regions each extend in a second horizontal direction in the planar top view, and wherein the second horizontal direction is different from the first horizontal direction;
forming a plurality of source/drain components over the active regions;
forming a dielectric structure over the source/drain components;
removing the dummy gate structure, wherein a removal of the dummy gate structure exposes a first segment of each of the active regions; and
reducing a thickness of the first segment of each of the active regions in the first horizontal direction.

9. The method of claim 8, wherein the reducing the thickness is performed by one or more etching processes.

10. The method of claim 9, wherein:
the dummy gate structure includes a dummy gate electrode and a gate spacer structure;
the removing of the dummy gate structure removes the dummy gate electrode but not the gate spacer structure or the dielectric structure; and
the dielectric structure and the gate spacer structure protect portions of the active regions disposed below from being etched during the one or more etching processes.

11. The method of claim 8, wherein:
each of the active regions includes a second segment that is covered by the dielectric structure; and
a thickness of the second segment of each of the active regions is unaffected by the reducing of the thickness of the first segment of each of the active regions in the first horizontal direction.

12. The method of claim 11, wherein for each of the active regions, the first segment is continuous with the second segment after the thickness of the first segment has been reduced.

13. The method of claim 11, wherein:
the first segment has a first thickness in the first horizontal direction;
the second segment has a second thickness in the first horizontal direction; and
a ratio between the second thickness and the first thickness is in a range between about 4:1 and about 6:1.

14. The method of claim 8, wherein the forming the plurality of source/drain components is performed via an epitaxial growth process, such that the source/drain components grown on adjacent active regions merge into one another in the first horizontal direction.

15. The method of claim 8, further comprising: after the reducing the thickness of the first segment, forming a metal-containing gate structure over the first segment of each of the active regions.

16. The method of claim 8, further comprising: forming a plurality of vertically protruding fin structures as the plurality of active regions, wherein the dummy gate structure is formed such that it partially wraps around each of the vertically protruding fin structures.

17. A device, comprising:
an active region that protrudes upwards in a vertical direction in a cross-sectional side view;
a gate structure that at least partially wraps around the active region in the cross-sectional side view;
wherein:
the gate structure extends in a first horizontal direction in a top view;
the active region extends in a second horizontal direction in the top view, the second horizontal direction being different from the first horizontal direction; and
a first portion of the active region located outside of the gate structure is thicker in the first direction than a second portion of the active region wrapped under the gate structure.

18. The device of claim 17, wherein the first portion of the active region is in direct physical contact with the second portion of the active region.

19. The device of claim 17, wherein the first portion of the active region is at least 1.3 times thicker than the second portion of the active region in the first horizontal direction.

20. The device of claim 17, wherein:
the active region is a first fin structure;
the device further comprises a second fin structure that is substantially parallel to the first fin structure;
a dielectric structure overlaps with both the first portion of the first fin structure and a third portion of the second fin structure in the top view;
the gate structure overlaps with both the second portion of the first fin structure and a fourth portion of the second fin structure in the top view;
a first distance separates the first portion of the first fin structure and the third portion of the second fin structure;
a second distance separates the second portion of the first fin structure and the fourth portion of the second fin structure; and
the second distance is at least 1.3 times greater than the first distance.
